(19) United States
(12) Patent Application Publication
(10) Pub. No.: US 2020/0098792 A1
(43) Pub. Date: Mar. 26, 2020

(54) ARRAY SUBSTRATE, MANUFACTURING METHOD OF THE ARRAY SUBSTRATE, AND DISPLAY PANEL

(71) Applicant: HKC Corporation Limited, Shenzhen (CN)

(72) Inventor: Huailiang He, Shenzhen (CN)

(21) Appl. No.: 16/254,586

(22) Filed: Jan. 22, 2019

Related U.S. Application Data
(63) Continuation of application No. PCT/CN2018/116669, filed on Nov. 21, 2018.

(30) Foreign Application Priority Data
Sep. 21, 2018 (CN) 201811111892.7

(51) Int. Cl. H01L 27/12; G02F 1/1362; G02F 1/1368

(52) U.S. Cl. CPC H01L 27/124; H01L 27/1225; H01L 27/1288; G02F 2001/136222; G02F 1/136286; G02F 1/1368; H01L 27/127

(57) ABSTRACT

The present disclosure discloses an array substrate, a manufacturing method of the array substrate, and a display panel. The manufacturing method includes: forming a gate electrode and a conductive isolation layer covering the gate electrode by patterning a first metal layer and a first conductive layer with a first mask.

### CROSS REFERENCE TO RELATED APPLICATIONS

The present application is a Continuation Application of PCT Application No. PCT/CN2018/116669 filed on Nov. 21, 2018, which claims the benefit of Chinese Patent Application No. 201811111892.7, filed on Sep. 21, 2018, which is incorporated herein by reference in its entirety.

### FIELD

The present disclosure relates to the field of electronic circuit technology, and in particular, relates to an array substrate, a manufacturing method of the array substrate, and a display panel.

### BACKGROUND

One array substrate of display devices is generally defined with one or more thin film transistors. To manufacture a gate electrode, a metal layer is commonly used in the manufacturing process of the thin film transistor. However, metal ions tend to diffuse in the subsequent high-temperature process, and then affect the switching characteristics of the thin film transistor, which results in abnormal display, or makes it prone to generate unevenness of the gate electrode and then results in tip discharge, and affecting the lifetime of the thin film transistor.

### SUMMARY

The main purpose of the present disclosure is to provide an array substrate, a manufacturing method of the array substrate, and a display panel, aiming to ensure the stability of the thin film transistor of the array substrate.

In order to achieve the above object, the present disclosure provides a manufacturing method of an array substrate, which includes the following operations:

providing a substrate;

depositing the first metal layer and the first conductive layer on the substrate, and forming the gate electrode and the conductive isolation layer covering the gate electrode by patterning the first metal layer and the first conductive layer with the first mask;

depositing a semiconductor layer and a second metal layer on a gate insulating layer after deposition of the gate insulating layer on the gate, and forming an active layer by patterning the semiconductor layer, forming a source electrode, a drain electrode and a pixel electrode by patterning the second metal layer with a second mask.

Optionally, the operation of depositing the first metal layer and the first conductive layer on the substrate, and forming the gate electrode and the conductive isolation layer covering the gate electrode by patterning the first metal layer and the first conductive layer with the first mask specifically includes:

depositing the first metal layer on the substrate, forming the gate electrode by patterning the first metal layer with the first mask; and

depositing the first conductive layer on the gate electrode and forming the conductive isolation layer by patterning the first metal layer with the first mask.

Optionally, the operation of depositing the first metal layer on the substrate specifically includes:

forming the first metal layer on the substrate by physical vapor deposition or sputtering deposition.

Optionally, the operation of depositing the first conductive layer on the gate specifically includes:

covering the first conductive layer on the gate electrode by physical vapor deposition.

Optionally, the operation of depositing the first metal layer and the first conductive layer on the substrate, and forming the gate electrode and the conductive isolation layer covering the gate electrode by patterning the first metal layer and the first conductive layer with the first mask specifically includes:

the first metal layer is copper or copper alloy; and

the first conductive layer is a laminated structure of one or more multi-metal oxide conductive materials selected from a group consisting of indium tin oxide, indium zinc oxide, aluminum doped zinc oxide, indium gallium zinc oxide, tin zinc oxide, and the like.

Optionally, the operation of depositing the first metal layer and the first conductive layer on the substrate, and forming the gate electrode and the conductive isolation layer covering the gate electrode by patterning the first metal layer and the first conductive layer with the first mask specifically includes:

sequentially depositing the first metal layer and the first conductive layer on the substrate, and forming the gate electrode and the conductive isolation layer covering the gate electrode by patterning the first metal layer and the first conductive layer with the first mask.

Optionally, the operation of sequentially depositing the first metal layer and the first conductive layer on the substrate specifically includes:

forming the first metal layer on the substrate by physical vapor deposition or sputtering deposition, and then covering the first conductive layer on the first metal layer by physical vapor deposition.

Optionally, the operation of depositing the first metal layer and the first conductive layer on the substrate, and forming the gate electrode and the conductive isolation layer covering the gate electrode by patterning the first metal layer and the first conductive layer with the first mask specifically includes:

the first metal layer is copper or copper alloy; and

the first conductive layer is a laminated structure of one or more multi-metal oxide conductive materials selected from a group consisting of indium tin oxide, indium zinc oxide, aluminum doped zinc oxide, indium gallium zinc oxide, tin zinc oxide, and the like.

Optionally, the process of patterning the semiconductor layer to form the active layer includes:

patterning the semiconductor layer with a third mask to form the active layer.

Optionally, after forming the source, the drain and the pixel electrode, the manufacturing method of the array substrate further includes:

depositing a passivation layer on the surfaces of the source electrode, the drain electrode and the pixel electrode, and patterning the passivation layer by using a fourth mask.

The present disclosure also provides an array substrate, which includes:

a substrate;

a gate electrode and a conductive isolation layer covering the gate electrode;

a gate insulating layer, defined on one side of the substrate facing the gate electrode and the conductive isolation layer, and covering the conductive isolation layer;

the active layer and the second metal layer, sequentially overlapped on the gate insulating layer, the second metal layer including the source electrode, the drain electrode and the pixel electrode, and the source electrode electrically connecting the drain electrode through the active layer.

Optionally, the gate electrode is made of copper or copper alloy material; and

the conductive isolation layer is a laminated structure of one or more multi-metal oxide conductive materials selected from a group consisting of indium tin oxide, indium zinc oxide, aluminum doped zinc oxide, indium gallium zinc oxide, tin zinc oxide, and the like.

Optionally, the second metal layer further includes a data line, and the data line is formed by patterning the second metal layer with a second mask.

Optionally, the pixel electrode further includes a passivation layer, and the passivation layer is overlapped on the second metal layer.

The present disclosure also provides a display panel including a color film substrate, a liquid crystal layer and the array substrate as described above.

the array substrate is defined with the pixel electrode thereon, and the color film substrate is defined with a common electrode thereon;

the liquid crystal layer is defined between the color film substrate and the array substrate;

the display panel controls the deflection of the liquid crystal molecules of the liquid crystal layer through the voltage difference between the pixel electrode and the common electrode, and displays an image through the color film substrate.

Optionally, the gate electrode is made of copper or copper alloy material; and

the conductive isolation layer is a laminated structure of one or more multi-metal oxide conductive materials selected from a group consisting of indium tin oxide, indium zinc oxide, aluminum doped zinc oxide, indium gallium zinc oxide, tin zinc oxide, and the like.

Optionally, the second metal layer further includes a data line, and the data line is formed by patterning the second metal layer with a second mask.

Optionally, the pixel electrode further includes a passivation layer, and the passivation layer is overlapped on the second metal layer.

According to the manufacturing method of the array substrate, the array substrate is manufactured by depositing the first metal layer and the first conductive layer on the substrate, forming the gate electrode and the conductive isolation layer covering the gate electrode by patterning the first metal layer and the first conductive layer with the first mask, and depositing a semiconductor layer and a second metal layer on a gate insulating layer after deposition of the gate insulating layer on the gate, forming the active layer by patterning the semiconductor, forming a source electrode, a drain electrode and a pixel electrode by patterning the second metal layer with a second mask. According to the present disclosure, the conductive isolation layer formed by patterning the first conductive layer covers the gate electrode layer to fully cover the gate electrode, thereby preventing diffusion of metal ions such as copper ions to the active layer of the thin film transistor in the subsequent high-temperature process which adversely affects the switching characteristics of the thin film transistor and other electrical properties of the thin film transistor, and ensuring the stability of the thin film transistor. According to the present disclosure, the conductive isolation layer is covered on the gate electrode so as to cover the metal burrs on the gate electrode which are generated on the lateral side of the gate electrode at the angle formed by photoetching, thus preventing the metal burrs from being exposed outside the gate electrode which generates tip discharge.

### BRIEF DESCRIPTION OF THE DRAWINGS

In order to more clearly explain the embodiments of the present disclosure or the technical solutions in the prior art, the drawings that need to be used in the embodiments or the description of the prior art will be briefly introduced below. Obviously, the drawings in the following description are only some embodiments of the present disclosure. For those of ordinary skill in the art, other drawings may be obtained according to the structures shown in these drawings without paying creative labor.

FIG. 1 is a flowchart of a manufacturing method of an array substrate in some embodiments of the present disclosure;

FIG. 2 is a schematic diagram of the operation S200 of a manufacturing method of an array substrate in some embodiments of the present disclosure;

FIG. 3 and FIG. 4 is a schematic diagram of the operation S300 of a manufacturing method of an array substrate in some embodiments of the present disclosure;

FIG. 5 is a partial structural diagram of an array substrate in some embodiments of the present disclosure;

FIG. 6 is a structural diagram of a display panel in some embodiments of the present disclosure.

### BRIEF DESCRIPTION OF THE DRAWINGS

| Label | Name |
|---|---|
| 10 | substrate |
| 20 | gate electrode |
| 30 | conductive isolation layer |
| 40 | gate insulating layer |
| 50 | active layer |
| 60 | source electrode |
| 70 | drain electrode |
| 80 | pixel electrode |
| 90 | passivation layer |
| 100 | array substrate |
| 200 | color film substrate |
| 300 | liquid crystal layer |

The realization, functional features and advantages of the purpose of the present disclosure will be further described with reference to the accompanying drawings in conjunction with the embodiments.

### DETAILED DESCRIPTION OF THE EMBODIMENTS

In order to make the purpose, technical scheme and advantages of the.

The technical scheme in the embodiment of the present disclosure will be described clearly and completely in the following with reference to the drawings in the embodiment of the present disclosure. Obviously, the described embodiment is only a part of the embodiment of the present disclosure, but not all of the embodiments. All other embodiments obtained by persons skilled in the art based on the embodiments of the present disclosure without creative efforts shall fall within the protection scope of the present disclosure.

It should be noted that if directional indications (such as up, down, left, right, front, back, etc.) are involved in the embodiments of the present disclosure, the directional indications are only used to explain the relative positional relationship and movement between the components in a certain posture (as shown in the drawings), and if the specific posture changes, the directional indications will change accordingly.

In addition, if there are descriptions of “first” and “second” in the embodiments of the present disclosure, the descriptions of “first” and “second” are used for descriptive purposes only and cannot be understood as indicating or implying their relative importance or implicitly indicating the number of indicated technical features. Thus, features defining “first” and “second” may explicitly or implicitly include at least one such feature. In addition, the technical solutions between the various embodiments may be combined with each other, but must be based on what one of ordinary skill in the art may achieve. When the combination of technical solutions is contradictory or impossible to achieve, it should be considered that the combination of such technical solutions does not exist and is not within the scope of protection required by the present disclosure.

The present disclosure provides a manufacturing method of an array substrate.

The array substrate is used for manufacturing a display device which is defined with a display panel, such as a television, a mobile phone, a computer, etc. The array substrate is generally defined with a thin film transistor (TFT), a pixel electrode, a common electrode, a common signal line, a data line, a scan line and other elements. The scan line is electrically connected to the gate electrode of the thin film transistor, the data line and pixel electrode are respectively electrically connected to one selected from a group consisting of the source electrode and the drain electrode of the thin film transistor, the scan line provides a scan signal to control the connection or disconnection between the source electrode and the drain electrode. When the source and drain are connected, the data line transmits a data signal to control the voltage of the pixel electrode, the common signal line is electrically connected to the common electrode and controls the voltage of the common electrode, and the voltage difference between the pixel electrode and the common electrode is controlled, and thereby an image is displayed by the display panel.

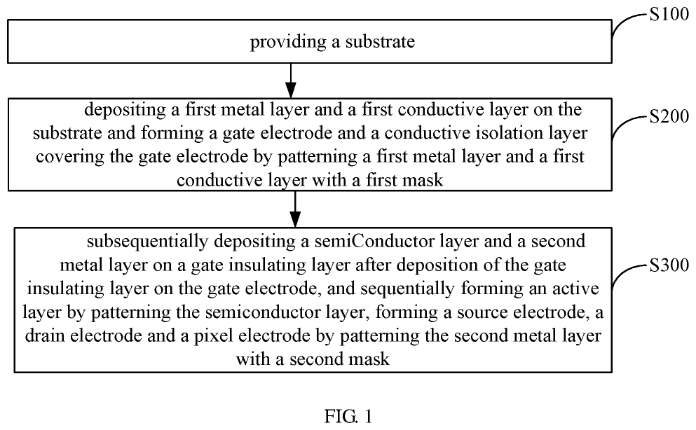

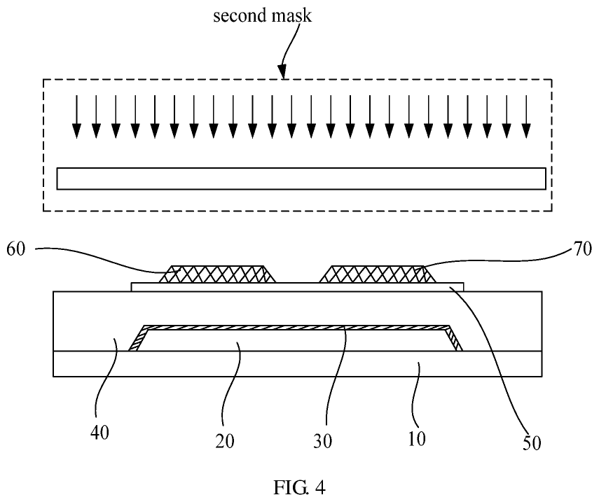

Referring to FIGS. 1 and 4, in some embodiments of the present disclosure, the manufacturing method of the array substrate 100 includes:

Step S100, providing a substrate 10;

In this embodiment, the substrate 10 is transparent, and the transparent substrate 10 may be a rigid one made of transparent materials such as glass or plastic.

Step S200: depositing the first metal layer and the first conductive layer on the substrate 10, and forming the gate electrode 20 and the conductive isolation layer 30 covering the gate electrode 20 by patterning the first metal layer and the first conductive layer with the first mask.

The first metal layer may be formed on the substrate 10 by physical vapor deposition (PVD) or sputtering deposition process, and be annealed to activate the metal layer, although other processes known to those skilled in the art may be implemented without limitation here.

The first metal layer may be made of a metal material such as copper Cu, molybdenum Mo, titanium Ti, aluminum Al, chromium Cr, silver Ag, gold Au, etc., and may be realized, for example, with a single metal layer of the above metal, or with a composite metal layer composed of any two or more metals. This embodiment may be made of a single copper metal layer. The conductive isolation layer 30 may be a laminated structure of one or more multi-metal oxide conductive materials among multi-metal oxide conductive materials such as indium tin oxide (ITO), indium zinc oxide (IZO), aluminum doped zinc oxide (AZO), indium gallium zinc oxide (IGZO), zinc tin oxide (ZTO), etc.

The first mask includes an exposure area corresponding to the patterns of the gate electrode 20 and the conductive isolation layer 30 covering the gate electrode 20 which are to be formed, UV light, yellow light or other light sources are irradiated toward the substrate 10 from the side of the first mask facing away from the substrate 10, and after exposing the first metal layer and the first conductive layer in the exposure area, the gate electrode 20 and the conductive isolation layer 30 of specific patterns are formed through an etching process, the etching process may be implemented by a dry etching process or a wet etching process. Specifically, under the protection of the photoresist mask, a wet etching process may be applied to etch the metal layer and the conductive isolation layer 30 to remove the portions of the metal layer and the conductive isolation layer 30 that are not covered by the photoresist mask. The gate electrode 20 formed by patterning the first metal layer is used to subsequently form a thin film transistor. The conductive isolation layer 30 formed by patterning the first conductive layer covers the gate electrode 20 layer, since the line width loss of the gate electrode 20 after etching is smaller than that of the conductive isolation layer 30, the conductive isolation layer 30 may fully cover the gate electrode 20, thereby preventing diffusion of metal ions such as copper ions to the active layer 50 of the thin film transistor in the subsequent high-temperature process which adversely affects the switching characteristics of the thin film transistor and other electrical properties of the thin film transistor, and ensuring the stability of the thin film transistor. In terms of fine structure, metal burrs may possibly be generated on a lateral side of the gate electrode 20 at the slope angle formed after photolithography. By defining the conductive isolation layer 30, the metal burrs on the gate electrode 20 may be better covered, which is conducive to preventing the metal burrs from being exposed outside the gate electrode 20, thereby preventing tip discharge.

Step S300: After depositing the gate insulating layer 40 on the gate electrode 20, sequentially depositing a semiconductor layer and a second metal layer on the gate insulating layer 40, patterning the semiconductor layer to form the active layer 50, and patterning the second metal layer to form the source electrode 60, the drain electrode 70, and the pixel electrode 80 with a second mask.

In this embodiment, the material of the gate insulating layer 40 may be a laminated structure of one or more insulating dielectric materials such as SiOx, SiNx, HFO₂, Al₂O₃, etc., and the gate insulating layer 40 may be formed by a chemical vapor deposition process or other processes, or other processes known to those skilled in the Art. A coated photoresist is deposit on that gate insulating lay 40. Exposure is performed through a mask, the mask divides the gate insulating layer 40 into a non-exposed area and an exposed area, and the exposed area is located on the gate 20 layer. The exposed substrate 10 is developed to retain the photoresist in the non-exposed area. The gate insulating layer 40 not covered by the photoresist is incompletely etched to form the gate insulating layer 40, the gate insulating layer 40 isolates the gate 20 from the active layer 50 which is subsequently formed on the gate insulating layer 40.

The semiconductor layer may be an oxide thin film layer, which may be formed by performing chemical vapor deposition on a laminated structure of one or more multi-metal oxide conductive materials among indium gallium zinc oxide (IGZO), aluminum doped zinc oxide (AZO), indium zinc oxide (IZO), indium gallium zinc oxide (IGTO), tin zinc oxide (ZTO), etc. Of course, other processes known to those skilled in the art may also be used. After forming the semiconductor layer, the photoresist layer may be exposed and developed with a gray mask process to obtain a photoresist mask, and under the protection of the photoresist mask, the semiconductor layer may be etched with a dry etching process to etch away the portion of the semiconductor layer not covered by the photoresist mask, thereby forming the active layer 50 of the thin film transistor 20.

The second metal layer may be made of a metal material such as copper Cu, molybdenum Mo, titanium Ti, aluminum Al, chromium Cr, silver Ag, gold Au, etc., and may be realized, for example, with a single metal layer of the above metal, or with a composite metal layer composed of any two or more metals. The metal thin film is formed by physical vapor deposition (PVD) or magnetron sputtering.

After the formation of the film, the source electrode 60 and the drain electrode 70 may be formed by patterning the second metal layer with a second mask, and the data line is formed by patterning the second metal layer with the second mask, and the data line is electrically connected to the source electrode 60 or the drain electrode 70. Specifically, the second mask includes an exposure area pattern corresponding to the data line, so as to form the data line while forming the source 60 and drain 70 by exposure. The data line outputs a data voltage to the source 60 or the drain 70, thereby controlling the pixel voltage of the pixel electrode 80. The formation of the data line, the source electrode 60 and the drain electrode 70 in the same mask exposure may effectively reduce the manufacturing process of the array substrate 100 of the display panel, thereby reducing the manufacturing costs of the array substrate 100 and the liquid crystal display.

In terms of fine structure, a lateral side of the source electrode 60 and the drain electrode 70 may exist metal burrs. By defining the passivation layer 90, the metal burrs on the source electrode 60 and the drain electrode 70 may be better covered, and exposure of the metal burrs outside the protective layer may be effectively prevented, so that the protective layer may better protect the source electrode 60 and the drain electrode 70, thus effectively avoiding adverse effects on the subsequent processes of the source electrode 60 and the drain electrode 70, and thereby significantly improving the yield of the display panel. Moreover, the color photoresist layer is defined between the two passivation layers 90, which may protect the color photoresist layer very well and effectively prevent the organic material of the color photoresist layer from releasing some harmful impurity gases in the subsequent process, thus realizing the effective protection of the display panel and increasing its efficiency and service life.

It may be understood that the above-mentioned primary mask process refers to the patterning process using a mask plate mask. In the above-mentioned photomask process, there are processes such as gluing, exposure, development, etching and stripping, etc., and in the etching process, dry etching or wet etching may be used to implement the above-mentioned manufacturing of array substrate 100, and those skilled in the art may use the known manufacturing process of array substrate 100 to implement the manufacturing of the above-mentioned array substrate 100, which will not be described here.

According to the manufacturing method of the array substrate 100 of the present disclosure, a first metal layer and a first conductive layer are deposited on a provided substrate 10, and the first metal layer and the first conductive layer are patterned with a first mask to form a gate electrode 20 and a conductive isolation layer 30 that covers the gate electrode 20; After the gate insulating layer 40 is deposited on the gate 20, a semiconductor layer and a second metal layer are sequentially deposited on the gate insulating layer 40, and the semiconductor layer is patterned to form the active layer 50; the source electrode 60, the drain electrode 70 and the pixel electrode 80 are formed by patterning the second metal layer with a second mask, thus completing the manufacturing of the array substrate 100. According to the present disclosure, the conductive isolation layer 30 formed by patterning the first conductive layer covers the gate electrode 20 layer to fully cover the gate electrode 20, thereby preventing diffusion of metal ions such as copper ions to the active layer 50 of the thin film transistor in the subsequent high-temperature process which adversely affects the switching characteristics of the thin film transistor and other electrical properties of the thin film transistor, and ensuring the stability of the thin film transistor. According to the present disclosure, the conductive isolation layer 30 is covered on the gate electrode 20 so as to cover the metal burrs on the gate electrode 20 which are generated on the lateral side of the gate electrode 20 at the angle formed by photoetching, thus preventing the metal burrs from being exposed outside the gate electrode 20 which generates tip discharge.

Referring to FIG. 1, in an optional embodiment, the operation of depositing a first metal layer and a first conductive layer on the substrate 10, and patterning the first metal layer and the first conductive layer with a first mask to form a gate electrode 20 and a conductive isolation layer 30 covering the gate electrode 20 specifically includes:

sequentially depositing the first metal layer and the first conductive layer on the substrate 10, and forming the gate electrode 20 and the conductive isolation layer 30 covering the gate electrode 20 by patterning the first metal layer and the first conductive layer with the first mask.

In this embodiment, a physical vapor deposition (PVD) method may be used to form a film, or a sputtering deposition process may be used to form the first metal layer on the substrate 10, and then after the conductive isolation layer 30 is covered on the first metal layer by physical vapor deposition, the first metal layer and the first conductive layer may be patterned by a first mask process, that is, by processes such as gluing, exposure, development, etching and stripping, to form the gate electrode 20 and the conductive isolation layer 30 covering the gate electrode 20.

Referring to FIG. 1, in an optional embodiment, the operation of depositing a first metal layer and a first conductive layer on the substrate 10, and patterning the first metal layer and the first conductive layer with a first mask to form a gate electrode 20 and a conductive isolation layer 30 covering the gate electrode 20 specifically includes:

depositing the first metal layer on the substrate 10, forming the gate electrode 20 by patterning the first metal layer with the first mask;

depositing the first conductive layer on the gate electrode and forming the conductive isolation layer 30 by patterning the first metal layer with the first mask.

In this embodiment, a physical vapor deposition (PVD) method may be used to form a film, or a sputtering deposition process may be used to form the first metal layer on the substrate 10, and the first metal layer may be patterned by a first mask process, that is, by processes such as gluing, exposure, development, etching and stripping, to form the gate electrode 20. Then, the conductive isolation layer 30 is covered on the gate electrode 20 by physical vapor deposition, and then the first conductive layer is patterned by the first mask process, that is, by gluing, exposure, development, etching and stripping, to form the conductive isolation layer 30.

Referring to FIG. 4, in an optional embodiment, the process of patterning the semiconductor layer to form the active layer 50 includes:

the active layer 50 is formed by patterning the semiconductor layer with a third mask (not shown).

In this embodiment, transparent oxide semiconductor material such as indium gallium zinc oxide (IGZO), aluminum doped zinc oxide (AZO), indium zinc oxide (IZO), indium gallium zinc oxide (IGTO), tin zinc oxide (ZTO) and the like may be used to form a film by a magnetron sputtering method, a semiconductor layer is deposited on the prepared gate insulating layer 40, and an active layer 50 is formed by patterning the semiconductor layer with a third mask. And the third mask includes an exposure area corresponding to the pattern corresponding to the active layer 50, and ultraviolet light or other light sources are irradiated toward the substrate 10 from the side of the third mask facing away from the substrate 10, and form the active layer 50 of specific pattern by exposing the semiconductor in the exposure area.

After the active layer 50 is manufactured, a second metal layer may be deposited on the active layer 50, and the source electrode 60, the drain electrode 70 and the pixel electrode 80 may be formed by patterning the second metal layer with a second mask. The second mask includes an exposure area corresponding to the patterns of the source electrode 60, drain electrode 70 and pixel electrode 80 to be formed. UV light or other light source irradiates the substrate 10 from the side of the second mask facing away from the substrate 10, and specific patterns of the source electrode 60, drain electrode 70 and pixel electrode 80 are formed by exposing the second metal layer in the exposure area. The pixel electrode 80 and the source electrode 60 and the drain electrode 70 may be formed in the same mask exposure, i.e., the process of forming the pixel electrode 80 is combined with the process of forming the source electrode 60 and the drain electrode 70, omitting the mask exposure operation of forming the pixel electrode 80 separately, thereby reducing the one mask exposure operation and thus the manufacturing cost of the array substrate 100 and the display panel. Optionally, the formation of the pixel electrode 80, and the formation of the source electrode 60 and the drain electrode 70 may be respectively implemented by two masks. In some embodiments, the active layer 50, the source electrode 60, the drain electrode 70, and the pixel electrode 80 may also be formed in one mask exposure process, which may be implemented according to design requirements, without limitation here.

The present disclosure also provides an array substrate.

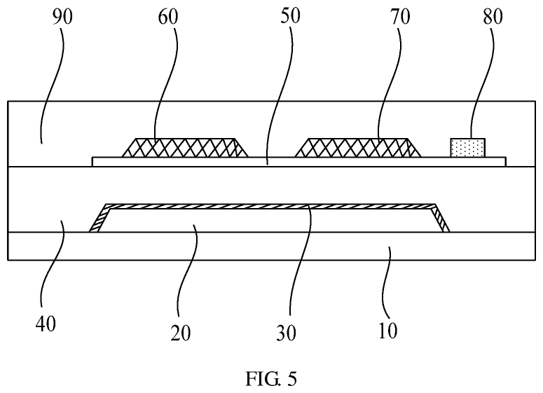

Referring to FIG. 5, in some embodiments of the present disclosure, the array substrate 100 includes:

a substrate 10;

a gate electrode 20 and a conductive isolation layer 30 covering the gate electrode 20;

a gate insulating layer 40, defined on the side of the substrate 10 facing the gate 20 and the conductive isolation layer 30, and covering the conductive isolation layer 30;

an active layer 50 and a second metal layer, sequentially overlapped on the gate insulating layer 40, the second metal layer includes a source 60, a drain 70 and a pixel electrode 80, and the source 60 and the drain 70 are electrically connected through the active layer 50.

In this embodiment, the gate electrode 20 and the conductive isolation layer 30 may be formed by depositing a first metal layer and a first conductive layer on the substrate 10, patterning the first metal layer and the first conductive layer with a first mask, and the first metal layer may be formed on the substrate 10 by physical vapor deposition (PVD) or by a sputtering deposition process. The first metal layer also includes a scan line electrically connected to the gate electrode 20, and the scan line outputs the gate electrode 20 voltage to the gate electrode 20, thereby controlling the on or off state of the thin film transistor. The gate electrode 20 is made of copper or copper alloy material.

The conductive isolation layer 30 is a laminated structure of one or more multi-metal oxide conductive materials among multi-metal oxide conductive materials such as indium tin oxide (ITO), indium zinc oxide (IZO), aluminum doped zinc oxide (AZO), indium gallium zinc oxide (IGZO), zinc tin oxide (ZTO), etc.

The gate insulating layer 40 is defined to isolate the gate 20 from the active layer 50 subsequently formed on the gate insulating layer 40.

The active layer 50 is formed as following: after forming the semiconductor layer on the gate insulating layer 40, the photoresist layer may be exposed and developed with a gray mask process to obtain a photoresist mask, and under the protection of the photoresist mask, the semiconductor layer may be etched with a dry etching process to etch away the portion of the semiconductor layer not covered by the photoresist mask.

The source electrode 60, the drain electrode 70, and the pixel electrode 80 may form a metal thin film by magnetron sputtering on the active layer 50, that is, after the first metal layer, the source electrode 60 and the drain electrode 70 may be formed by patterning the second metal layer with a second mask

The second metal layer also includes a data line, which may be formed by patterning the second metal layer through a second mask. The data line is electrically connected to the source electrode 60 or the drain electrode 70, and the gate electrode 20 outputs the voltage of the gate electrode 20 to connect the source electrode 60 and the drain electrode 70, thereby controlling the data line to output the data voltage to the source electrode 60 or the drain electrode 70, and further controlling the pixel voltage of the pixel electrode 80.

The pixel electrode 80 also includes a passivation layer 90 overlapped on the second metal layer. The passivation layer 90 is used to protect the source electrode 60, the drain electrode 70 and the pixel electrode 80 from oxidation.

In this embodiment, the amount of pixel electrodes 80 is plural, so that an electric field is formed between the pixel electrode 80 and the upper color film (CF) substrate 200 adjacent to the pixel electrode 80, thus controlling the deflection of liquid crystal molecules.

According to the present disclosure, the conductive isolation layer 30 formed by patterning the first conductive layer covers the gate electrode 20 layer to fully cover the gate electrode 20, thereby preventing diffusion of metal ions such as copper ions to the active layer 50 of the thin film transistor in the subsequent high-temperature process which adversely affects the switching characteristics of the thin film transistor and other electrical properties of the thin film transistor, and ensuring the stability of the thin film transistor. According to the present disclosure, the conductive isolation layer 30 is covered on the gate electrode 20 so as to cover the metal burrs on the gate electrode 20 which are generated on the lateral side of the gate electrode 20 at the angle formed by photoetching, thus preventing the metal burrs from being exposed outside the gate electrode 20 which generates tip discharge.

The present disclosure also provides a display panel.

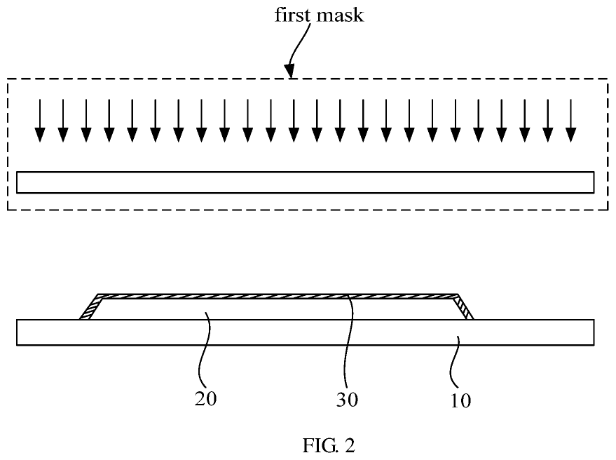

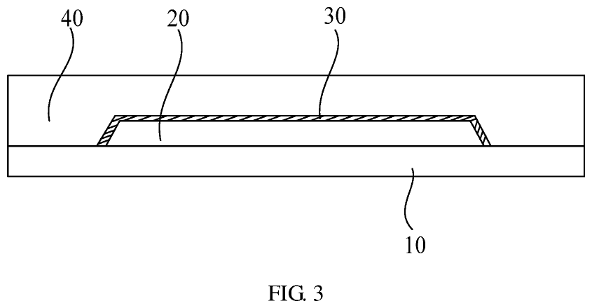

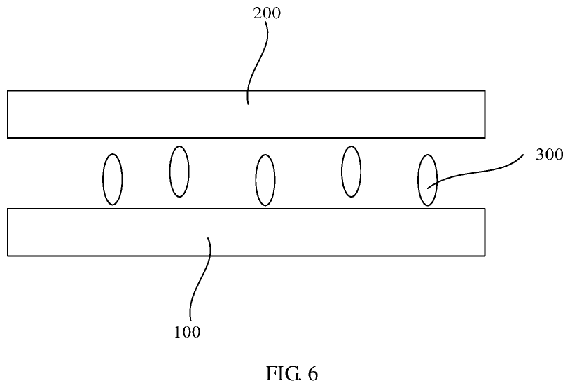

Referring to FIGS. 1 to 6, in some embodiments of the present disclosure, the display panel includes a color film substrate 200, a liquid crystal layer 300, and an array substrate 100 as described above. It is understood that the detailed structure of the array substrate 100 may refer to the embodiment described above and will not be described here. Since the array substrate 100 is used in the display panel of the present disclosure, the embodiment of the display panel of the present disclosure includes all the technical schemes of all the embodiments of the array substrate 100, and the technical effects achieved are exactly the same, which will not be described here.

The array substrate 100 is defined with a pixel electrode 80, and the color film substrate 200 is defined with a common electrode.

the liquid crystal layer 300 is defined between the color film substrate and the array substrate;

The display panel controls the deflection of liquid crystal molecules of the liquid crystal layer 300 through a voltage difference between the pixel electrode 80 and the common electrode (not shown) and displays an image through the color film substrate 200.

In this embodiment, it is understood that the common electrode may also be defined on the array substrate 100 and isolated from the gate electrode 20 by the gate insulating layer 40. After the display panel is powered on, the gate electrodes 20 of each thin film transistor on the array substrate 100 are connected to the gate electrode 20 driver of the display panel via the scan line on the array substrate 100. The source electrode 60 (or the drain electrode 70) on the thin film transistor is connected to the pixel electrode 80 via the data line on the array substrate 100, the pixel electrode 80 is connected to the source 60 driver of the display panel, and the drain electrode 70 (or source electrode 60) on the thin film transistor is electrically connected to the common electrode on the color film substrate 200. When the thin film transistor corresponding to the scanning row on the display panel is turned on via the control of the gate 20 driver and controls the data driver to output the corresponding data signal to the pixel electrode 80 via the data line, the display panel controls the deflection of the liquid crystal molecules of the liquid crystal layer 300 through the voltage difference between the pixel electrode 80 and the common electrode, and displays an image through the color film substrate 200.

The above are only the optional embodiments of the present disclosure and are not therefore limiting the scope of the patent disclosure. Any equivalent structural change made under the inventive concept of the present disclosure using the contents of the present disclosure specification and drawings, or directly/indirectly applied in other related technical fields, is included in the scope of the patent protection of the present disclosure.

What is claimed is:

1. A manufacturing method of an array substrate, wherein the manufacturing method comprises:
providing a substrate;
depositing a first metal layer and a first conductive layer on the substrate, forming a gate electrode and a conductive isolation layer covering the gate electrode by patterning the first metal layer and the first conductive layer with a first mask; and
depositing a semiconductor layer and a second metal layer sequentially on a gate insulating layer after deposition of the gate insulating layer on the gate electrode, forming an active layer by patterning the semiconductor layer, and forming a source electrode, a drain electrode, and a pixel electrode by patterning the second metal layer with a second mask.

2. The manufacturing method of the array substrate according to claim 1, wherein the operation of depositing a first metal layer and a first conductive layer on the substrate, and forming the gate electrode and the conductive isolation layer covering the gate electrode by patterning the first metal layer and the first conductive layer with a first mask specifically comprises:
depositing the first metal layer on the substrate, forming the gate electrode by patterning the first metal layer with the first mask; and
depositing the first conductive layer on the gate electrode and forming the conductive isolation layer by patterning the first metal layer with the first mask.

3. The manufacturing method of the array substrate according to claim 2, wherein the operation of depositing a first metal layer on the substrate specifically comprises:
forming the first metal layer on the substrate by physical vapor deposition or sputtering deposition.

4. The manufacturing method of the array substrate according to claim 2, wherein the operation of depositing the first conductive layer on the gate electrode specifically comprises:
covering the first conductive layer on the gate electrode by physical vapor deposition.

5. The manufacturing method of the array substrate according to claim 2, wherein the operation of depositing a first metal layer and a first conductive layer on the substrate, and forming a gate electrode and a conductive isolation layer covering the gate electrode by patterning the first metal layer and the first conductive layer with a first mask specifically comprises:
the first metal layer is copper or copper alloy; and
the first conductive layer is a laminated structure of one or more multi-metal oxide conductive materials selected from a group consisting of indium tin oxide, indium zinc oxide, aluminum doped zinc oxide, indium gallium zinc oxide, and tin zinc oxide.

6. The manufacturing method of the array substrate according to claim 1, wherein the operation of depositing a first metal layer and a first conductive layer on the substrate, and forming a gate electrode and a conductive isolation layer covering the gate electrode by patterning the first metal layer and the first conductive layer with the first mask specifically comprises:
sequentially depositing the first metal layer and the first conductive layer on the substrate, and forming the gate electrode and the conductive isolation layer covering the gate electrode by patterning the first metal layer and the first conductive layer with the first mask.

7. The manufacturing method of the array substrate according to claim 6, wherein the operation of sequentially depositing the first metal layer and the first conductive layer on the substrate specifically comprises:
forming the first metal layer on the substrate by physical vapor deposition or sputtering deposition, covering the first conductive layer on the first metal layer by physical vapor deposition.

8. The manufacturing method of the array substrate according to claim 6, wherein the operation of depositing a first metal layer and a first conductive layer on the substrate, and forming a gate electrode and a conductive isolation layer covering the gate electrode by patterning the first metal layer and the first conductive layer with a first mask specifically comprises:
the first metal layer is copper or copper alloy; and
the first conductive layer is a laminated structure of one or more multi-metal oxide conductive materials selected from a group consisting of indium tin oxide, indium zinc oxide, aluminum doped zinc oxide, indium gallium zinc oxide, and tin zinc oxide.

9. The manufacturing method of the array substrate according to claim 1, wherein the process of patterning the semiconductor layer to form the active layer comprises:
patterning the semiconductor layer with a third mask to form the active layer.

10. The manufacturing method of the array substrate according to claim 1, wherein after forming the source electrode, the drain electrode, and the pixel electrode, the manufacturing method of the array substrate further comprises:
depositing a passivation layer on the surfaces of the source electrode, the drain electrode, and the pixel electrode, and patterning the passivation layer using a fourth mask.

11. An array substrate, wherein the array substrate comprises:
a substrate;
a gate electrode and a conductive isolation layer covering the gate electrode;
a gate insulating layer, defined on one side of the substrate facing the gate electrode and the conductive isolation layer, and covering the conductive isolation layer; and
an active layer and a second metal layer, sequentially overlapped on the gate insulating layer, the second metal layer comprising a source electrode, a drain electrode, and a pixel electrode, and the source electrode electrically connecting the drain electrode through the active layer.

12. The array substrate according to claim 11, wherein,
the gate electrode is made of copper or copper alloy material; and
the conductive isolation layer is a laminated structure of one or more multi-metal oxide conductive materials selected from a group consisting of indium tin oxide, indium zinc oxide, aluminum doped zinc oxide, indium gallium zinc oxide, and tin zinc oxide.

13. The array substrate of claim 11, wherein the second metal layer further comprises a data line, and the data line is formed by patterning the second metal layer with a second mask.

14. The array substrate according to claim 11, wherein the pixel electrode further comprises a passivation layer, and the passivation layer is overlapped on the second metal layer.

15. A display panel comprising a color film substrate, a liquid crystal layer, and an array substrate,
the array substrate being defined with a pixel electrode thereon, and the color film substrate being defined with a common electrode thereon;
the liquid crystal layer being defined between the color film substrate and the array substrate; and
the display panel controlling the deflection of the liquid crystal molecules of the liquid crystal layer through the voltage difference between the pixel electrode and the common electrode, and displaying an image through the color film substrate;
the array substrate comprising:
a substrate; a gate electrode and a conductive isolation layer covering the gate electrode;
a gate insulating layer, defined on one side of the substrate facing the gate electrode and the conductive isolation layer, and covering the conductive isolation layer; and
an active layer and a second metal layer, sequentially overlapped on the gate insulating layer, the second metal layer comprising a source electrode, a drain electrode, and a pixel electrode, and the source electrode electrically connecting the drain electrode through the active layer.

16. The display panel according to claim 15, wherein the gate electrode is made of copper or copper alloy material;
the conductive isolation layer is a laminated structure of one or more multi-metal oxide conductive materials selected from a group consisting of indium tin oxide, indium zinc oxide, aluminum doped zinc oxide, indium gallium zinc oxide, and tin zinc oxide.

17. The display panel of claim 15, wherein the second metal layer further comprises a data line, and the data line is formed by patterning the second metal layer with a second mask.

18. The display panel according to claim 15, wherein the pixel electrode further comprises a passivation layer, and the passivation layer is overlapped on the second metal layer.
